(19) United States
(12) Patent Application Publication
(10) Pub. No.: US 2009/0325356 A1
(43) Pub. Date: Dec. 31, 2009

(54) METHODS OF FORMING A LOW TEMPERATURE DEPOSITION LAYER AND METHODS OF MANUFACTURING SEMICONDUCTOR DEVICE USING THE SAME

(76) Inventors: Dong-Woon SHIN, Seongnam-si (KR); Si-Young Choi, Seongnam-si (KR); Tai-Su Park, Seoul (KR); Jong-Ryeol Yoo, Osan-si (KR); Jong-Hoon Kang, Suwon-si (KR)

Correspondence Address: F. CHAU & ASSOCIATES, LLC, 130 WOODBURY ROAD, WOODBURY, NY, 11797, US

(21) Appl. No.: 12/432,500

(22) Filed: Apr. 29, 2009

(30) Foreign Application Priority Data
Jun. 26, 2008 (KR) 2008-60998

(51) Int. Cl. H01L 21/336; H01L 21/31; H01L 21/426

(52) U.S. Cl. 438/303; 438/765; 438/513; 257/E21.474; 257/E21.409; 257/E21.24

(57) ABSTRACT

Provided are methods of forming a low temperature deposition layer and methods of manufacturing a semiconductor device using the same. The method of manufacturing a semiconductor device comprises forming a mask layer exposing a gate pattern on a substrate on which the gate pattern is formed, forming a sacrifice layer on the mask layer and on a substrate not covered by the mask layer using a plasma ion immersion implantation and deposition (PIIID), and doping a substrate adjacent to both sidewalls of the gate pattern with an impurity.

### CROSS-REFERENCE TO RELATED APPLICATIONS

This U.S. non-provisional patent application claims priority under 35 U.S.C. § 119 of Korean Patent Application No. 2008-60998, filed on Jun. 26, 2008, the entire disclosure of which is hereby incorporated by reference herein in its entirety.

### BACKGROUND

1. Technical Field

The present disclosure relates to methods of forming a low temperature deposition layer and methods of manufacturing semiconductor device using the same, and more particularly, to a method of forming a deposition layer using a plasma deposition at a low temperature and a method of manufacturing a semiconductor device using the same.

2. Description of the Related Art

Integration circuit devices are widely used in various application devices. As is well known, integration circuit devices may include many active elements such as, for example, a transistor formed on a substrate such as, for example, a silicon wafer. Also, the manufacturing of integration circuit devices may include many masking steps which selectively expose regions of various layers including a substrate. For example, when manufacturing a semiconductor device such as a complementary metal oxide semiconductor field effect transistor (CMOSFET), impurities selectively are generally implanted into an active region of a substrate using various masks.

As a semiconductor device such as an integration circuit device is continuously highly integrated and/or more complicated, the number of masking step is also increased, thereby providing a more complicated process with increased costs. Thus, the need for a more simplified process for manufacturing a semiconductor device is increased. In the meantime, various deposition layers forming a semiconductor device are generally formed at a comparatively high temperature. However, when a layer is deposited at a high temperature, different layers may be thermally affected to have a thermal burden such as a thermal budget. Accordingly, as a result, methods of depositing a layer at a low temperature may be required.

### SUMMARY

Some exemplary embodiments provide a method of forming a low temperature deposition layer. The method includes providing a reaction gas to a substrate; applying a bias to the substrate; and forming a deposition layer on the substrate by plasma deposition using plasma ion immersion implantation and deposition (PIIID).

Some exemplary embodiments provide a method of manufacturing a semiconductor device. The method includes forming a mask layer exposing a gate pattern on a substrate including the gate pattern; forming a sacrifice layer on the mask layer and on a substrate not covered by the mask layer using plasma ion immersion implantation and deposition (PIIID) and doping a substrate adjacent to both sidewalls of the gate pattern with an impurity.

Some exemplary embodiments provide a method of manufacturing a semiconductor device. The method includes forming a gate pattern on an active region of a substrate and implanting a low concentration impurity and a high concentration impurity into the substrate to form a lightly doped drain and a high concentration deep source/drain in an active region adjacent to both sidewalls of the gate pattern. The forming of the lightly doped drain includes forming a mask layer on the substrate and implanting the low concentration impurity into the active region adjacent to both sidewalls of the gate pattern by plasma doping using plasma ion immersion implantation and deposition (PIIID). Also, the forming of the high concentration deep source/drain includes forming a sacrifice layer on an entire surface of the substrate by a plasma deposition using the PIIID and implanting the high concentration impurity into the lightly doped drain by a plasma doping using the PIIID to form the high concentration deep source/drain having a small width and a great depth compared with the lightly doped drain.

Some exemplary embodiments provide a method of manufacturing a semiconductor device. The method includes forming a gate pattern on an active region of a substrate; and sequentially implanting a low concentration impurity and a high concentration impurity into the substrate to sequentially form a lightly doped drain and a high concentration deep source/drain in an active region adjacent to both sidewalls of the gate pattern. The forming of the high concentration deep source/drain includes forming a sacrifice layer on an entire surface of the substrate by a plasma deposition using a plasma ion immersion implantation and deposition (PIIID) after forming a mask layer covering a portion of the substrate and implanting the high concentration impurity into the substrate by plasma doping using the PIIID to form the high concentration deep source/drain in the active region adjacent to both sidewalls of the gate pattern. Moreover, the forming of the lightly doped drain includes removing the sacrifice layer to expose the active region including the high concentration deep source/drain and the mask layer and implanting the low concentration impurity into the exposed active region including the high concentration deep source/drain by plasma doping using the PIIID using the exposed mask layer as an mask to form the lightly doped drain having a shallow depth compared with the high concentration deep source/drain.

Some exemplary embodiments provide a method of manufacturing a semiconductor device. The method includes forming a plurality of bit lines on a substrate; forming a bit line spacer on each of the plurality of bit lines by a plasma deposition using a plasma ion immersion implantation and deposition (PIIID), forming a contact electrically connected to the substrate between the plurality of the bit lines and forming a capacitor electrically connected to the contact.

### BRIEF DESCRIPTION OF THE DRAWINGS

Exemplary embodiments of the present invention can be understood in more detail from the following description taken in conjunction with the attached drawings, in which:

FIGS. 1A through 1K are cross sectional views of process steps illustrating a method of manufacturing a semiconductor device according to an exemplary embodiment of the present invention.

FIGS. 2A through 2M are cross sectional views of process steps illustrating a method of manufacturing a semiconductor device according to an exemplary embodiment of the present invention.

FIGS. 3A through 3K are cross sectional views of process steps illustrating a method of manufacturing a semiconductor device according to an exemplary embodiment of the present invention.

FIGS. 4A through 4K are cross sectional views of process steps illustrating a method of manufacturing a semiconductor device according to an exemplary embodiment of the present invention.

FIG. 5A is a graph showing a combination state of SiN obtained from a deposition process that a bias is not applied to a substrate in a method of manufacturing a semiconductor device according to an exemplary embodiment of the present invention.

FIG. 5B is a graph showing a combination state of SiN obtained from a deposition process that a bias is applied to a substrate in a method of manufacturing a semiconductor device according to an exemplary embodiment of the present invention.

FIG. 6A is a microphotograph of SiN obtained from a PIIID process that a bias is not applied to a substrate in a method of manufacturing a semiconductor device according to an exemplary embodiment of the present invention.

FIG. 6B is a microphotograph of SiN obtained from a PIIID process that a bias is applied to a substrate in a method of manufacturing a semiconductor device according to an exemplary embodiment of the present invention.

FIG. 7A is a top plan view depicting an application example of a PIIID low temperature deposition layer according to an exemplary embodiment of the present invention.

FIG. 7B is a cross sectional view taken along the line X-Y of FIG. 7A.

### DETAILED DESCRIPTION OF THE EXEMPLARY EMBODIMENTS OF THE INVENTION

The present invention now will be described more fully hereinafter with reference to the accompanying drawings, in which exemplary embodiments of the invention are shown. This invention may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Exemplary embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

### First Exemplary Embodiment

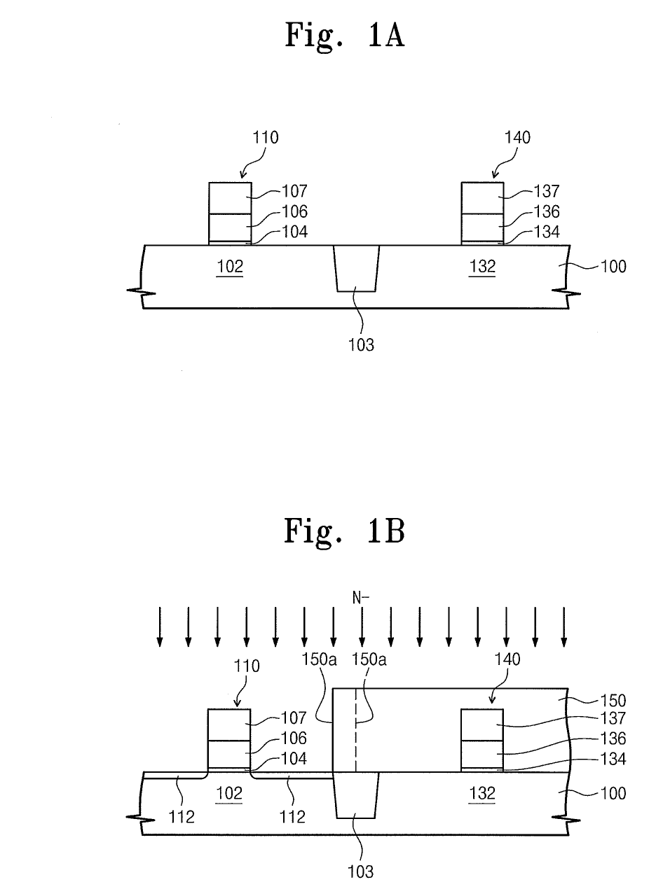

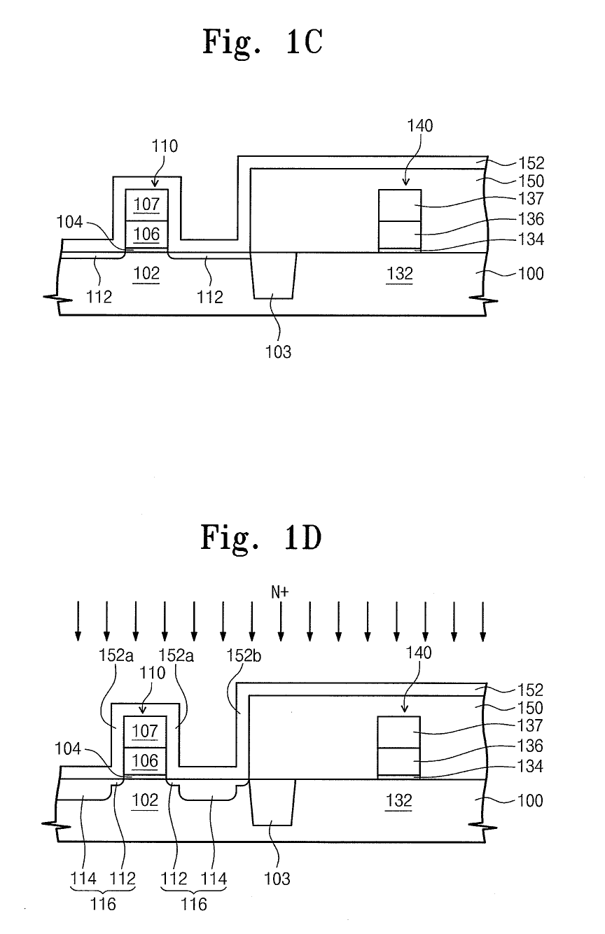

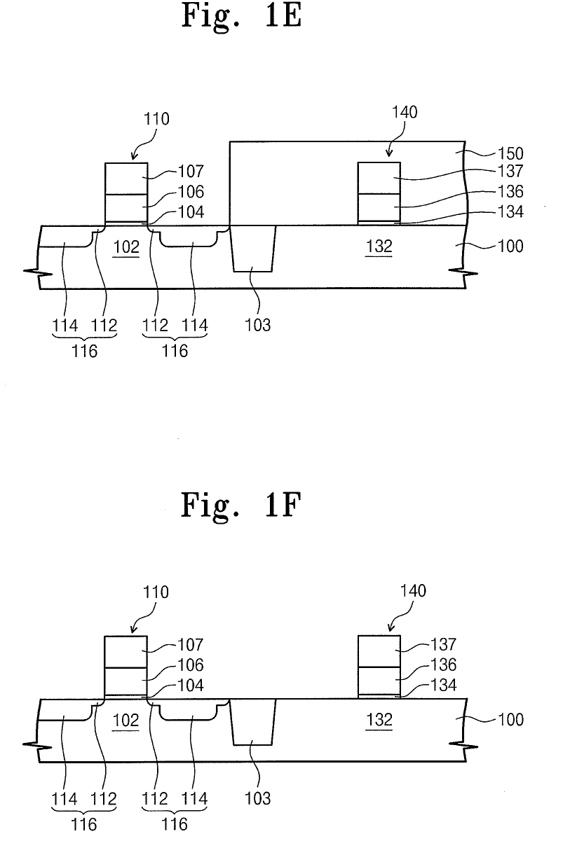

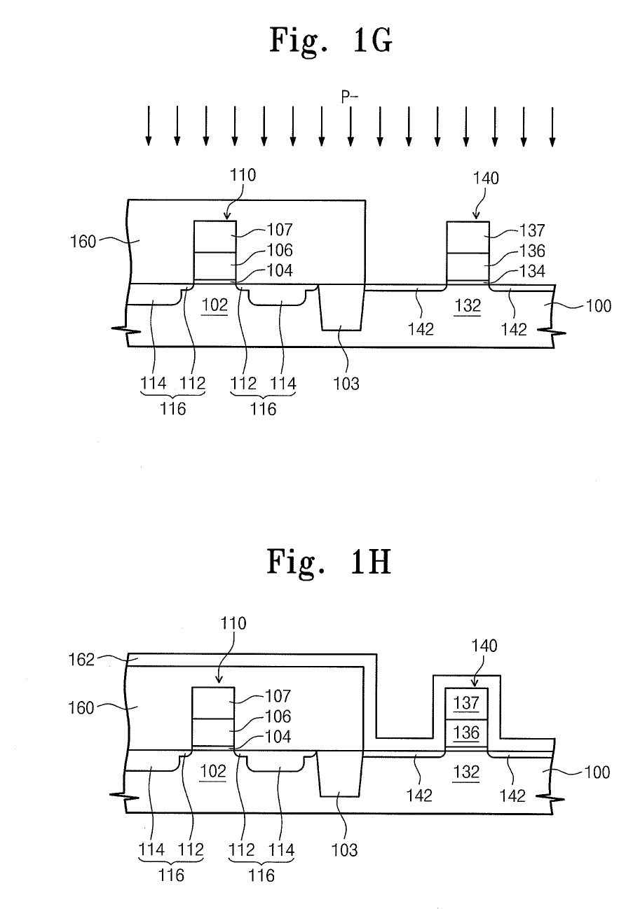

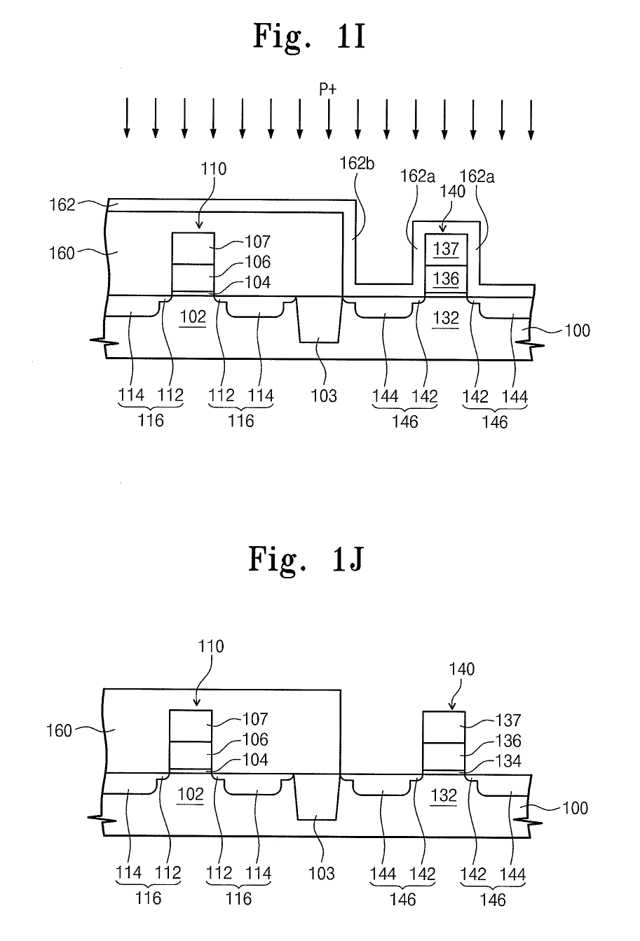

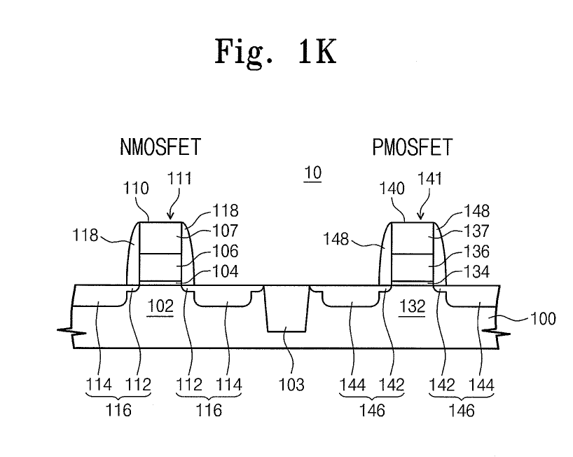

FIGS. 1A through 1K are cross sectional views of process steps illustrating a method of manufacturing a semiconductor device according to a first exemplary embodiment of the present invention.

Referring to FIG. 1A, a substrate 100 is divided into a first active region 102 and a second active region 132. The substrate 100 may be, for example, a silicon wafer or a silicon on insulator (SOI) substrate. The first and second active regions 102 and 132 are divided by a device isolation layer 103. The first and second active regions 102 and 132 may have a same conductivity type. Alternatively, the first and second active regions 102 and 132 may have an opposite conductivity type, such as, for example, the first active region 102 has a P conductivity type and the second active region 132 has an N conductivity type, to embody a CMOS device. The present exemplary embodiment will be described on the supposition that the first active region 102 has, for example, a P conductivity type and the second active region 132 has, for example, an N conductivity type. When the substrate 100 has a P type conductivity, the first active region 102 of a P conductivity type and the second active region 132 of an N conductivity type may be formed by forming a well of an N conductivity type in the second active region 132.

A first gate pattern 110 is formed on the first active region 102 and a second gate pattern 140 is formed on the second active region 132. The first gate pattern 110 may include a first gate insulating layer 104 and a first gate electrode 106. The second gate pattern 140 may include a second gate insulating layer 134 and a second gate electrode 136. The gate insulating layers 104 and 134 may have a width and an ingredient equal to or different from each other. For example, the gate insulating layers 104 and 134 may be formed of silicon oxide (SiO₂). The gate electrodes 106 and 136 may also have a width and an ingredient equal to or different from each other. For example, the gate electrodes 106 and 136 may be formed in a single layer type comprised of polysilicon or metal, or may be formed in a double layer type comprised of polysilicon and metal. The first gate pattern 110 may further include a first hard mask layer 107 on the first gate electrode 106. The second gate pattern 140 may also further include a second hard mask layer 137 on the second gate electrode 136.

Referring to FIG. 1B, a mask layer 150 is formed to cover one of the first and second active regions 102 and 132 and to not cover the other one. For example, the first mask layer 150 covering the second active region 132 may be formed by coating a photoresist on the entire surface of the substrate 100 and selectively removing a portion of the photoresist covering the first active region 102. For example, a portion 150a of the first mask layer 150 may be disposed adjacent to an edge of the device isolation layer 103. Alternatively, a portion 150a of the first mask layer 150 may be disposed adjacent to a central portion of the device isolation layer 103. The example of the former will be described in the present exemplary embodiment.

Materials used for forming the first mask layer 150 may be, for example, silicon (Si), silicon oxide (SiO₂), or silicon nitride (SiN) which can be comparatively easily deposited on the substrate 100 formed of silicon. However, when the first mask layer 150 is formed of one of these materials, a mask process for patterning may be needed. Also, when the substrate 100 is formed of silicon and the gate patterns 110 and 140 are formed of polysilicon and silicon oxide, the substrate 100 and/or the gate patterns 110 and 140 may be damaged by an etchant during the removal of the first mask 150. As will be described in FIG. 1g, as a comparatively high temperature may be needed when a second mask layer 160 is formed of silicon nitride, a profile of a junction region may be undesirably altered by a diffusion of impurities doped in the junction region. Thus, it is desirable that the first mask layer 150 is formed of photoresist.

After the first mask layer 150 is formed, a low concentration impurity is implanted into the first active region 102 adjacent to both side walls of the first gate pattern 110 using the first mask layer 150 as a mask to form a first lightly doped drain 112 (hereinafter, it is referred to as LDD). For example, the LDD 112 may be doped with an N conductivity type by adopting AsH₄ as an impurity. The first mask layer 150 may prevent an impurity from being implanted into the second active region 132 and the first hard mask layer 107 may prevent an impurity from being implanted into the first gate electrode 106.

For example, an ion doping using an ion implantation or plasma doping using a plasma ion immersion implantation and deposition (PIIID) may be adopted as a low concentration impurity doping for forming the first LDD 112. The PIIID may be represented as PIII & D or Pill. The plasma ion immersion implantation and deposition is represented by PIIID in the present exemplary embodiment.

An ion doping using an ion implantation is a thing that a material for doping is ionized to generate an ion beam. The ion beam is mass filtered to provide only the wanted dopant to a chamber and only the wanted dopant is accelerated to be implanted into the substrate 100. Plasma doping using PIIID is largely different from the ion doping in the view point that a material for doping is immersed in the plasma.

The ion doping may require very complicated equipment to ionize and accelerate a dopant, while the plasma doping does not need other equipment except for equipment generating plasma. Thus, the plasma doping may be performed using comparatively simple equipment and the cost for using the plasma doping may be low in comparison to ion doping. Also, the energy needed for the plasma doping is small compared with the energy needed for the ion doping and damage to the substrate during the plasma doping can be minimized. In addition, as the PIIID can perform an etching and deposition as well as doping, a series of processes may be continuously performed without exposing the substrate to the atmosphere to simplify a process if using the PIIID. In the present exemplary embodiment, the first LDD 112 is formed by adopting the plasma doping using the PIIID.

Referring to FIG. 1C, a first sacrifice layer 152 is formed on the entire surface of the substrate 100 without removing the first mask layer 150. The first sacrifice layer 152 may be formed of, for example, silicon, silicon oxide or silicon nitride readily deposited on the substrate 100 and the first mask layer 150.

The sacrifice layer 152 may be formed on the substrate 100 and the first gate pattern 110 at the first active region 102 and may be formed on the first mask layer 150 at the second active region 132. In other words, the sacrifice layer 152 may be in contact with silicon and silicon oxide at the first active region 102 and in contact with the photoresist at the second active region 132. Thus, as will be described later referring to FIG. 1E, the substrate 100 and/or the first gate pattern 110 should not be damaged by an etchant during a process of removing the first sacrifice layer 152. Silicon nitride (SiN) may be more desirable compared with silicon and silicon oxide (SiO₂) as a material forming the first sacrifice layer 152. The first sacrifice layer 152 may be formed by, for example, depositing silicon carbide (SiC). Silicon nitride (SiN) is adopted as a material of the first sacrifice layer 152 in the present exemplary embodiment.

The first sacrifice layer 152 is formed on the first mask layer 150 comprised of photoresist at the second active region 132. Silicon nitride (SiN) should be deposited at a temperature which does not burn the photoresist to form the first sacrifice layer 152. For example, silicon nitride (SiN) should be deposited at a low temperature under about 85 degrees centigrade to form the first sacrifice layer 152. Here, the low temperature may be defined herein as a temperature that a photoresist is not burned.

The first sacrifice layer 152 may be used as a disposable spacer for forming a first deep source/drain 114 as will be described later referring to FIG. 1D. Dopants may pass through the first sacrifice layer 152 and penetrate into the first active region 102 to form the first deep source/drain 114. Here, an area of the first deep source/drain 114 is smaller than the first LDD 112 and a depth of the first deep source/drain 114 is greater than the first LDD 112. If the first sacrifice layer 152 is not flat and does not have a fine structure, it may be difficult to get the first deep source/drain 114 having the desired profile. Thus, the first sacrifice layer 152 should be flat and have a fine structure to get the first deep source/drain 114 having the desired profile. The first sacrifice layer 152 may be formed by, for example, depositing SiN at a low temperature such that the first mask layer 150 is not burned.

The first sacrifice layer 152 may be formed by, for example, depositing SiN using an atomic layer deposition (ALD) process. The ALD process may need a deposition temperature of about more than 200 degrees centigrade. Thus, ALD process may not be desirable to deposit SiN.

The first sacrifice layer 152 may be formed by, for example, depositing SiN using a chemical vapor deposition (CVD) process. A silane (SiH₄) reaction gas is generally used to deposit SiN using a CVD process. A SiN layer obtained using SiH4 as a reaction gas may be a very porous and uneven layer having a large amount of hydrogen. In attempting to solve this difficulty, if setting a deposition temperature at a high temperature, the first mask layer 152 comprised of a photoresist may be burned. Thus, it may be difficult to deposit SiN having a fine structure at a low temperature using a CVD process.

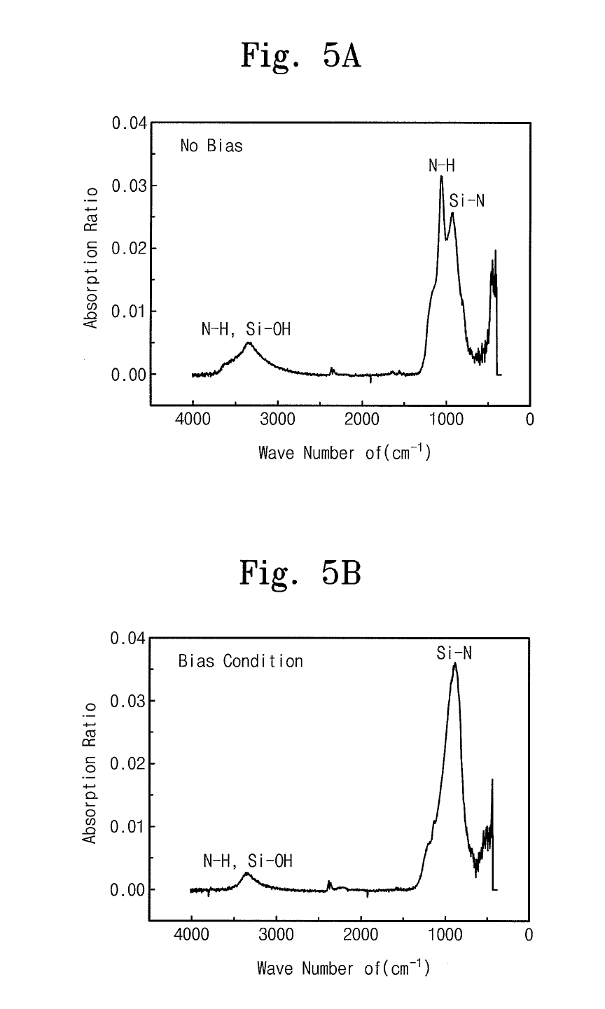

The first sacrifice layer 152 may be formed by, for example, depositing SiN using a plasma deposition using PIID. A plasma deposition is a kind of plasma enhanced chemical vapor deposition (PECVD) and can obtain SiN having a flat and fine structure at about 60 degrees centigrade. For example, when SiN is deposited using PIIID under the condition that a proper bias is applied to the substrate, almost complete Si—N combination can be formed as will be described later referring to FIGS. 5A and 5B. If adopting a plasma deposition using PIIID for the first sacrifice layer 152 formation process, a more simplified process may be embodied because the first sacrifice layer 152 and the first LDD 112 may be formed in-situ using plasma doping using PIID.

When forming the first sacrifice layer 152, the first sacrifice layer 152 may have a more fine structure by adding any one properly selected from a group consisting of, for example, boron (B), phosphorous (P), arsenic (As), oxygen (O), nitrogen (N), fluoride (F) and combinations thereof to silicon nitride (SiN) or silicon carbide (SiC). Also, the first sacrifice layer 152 described referring to FIG. 1E may be readily removed by adding any one properly selected from a group consisting of, for example, B, P, As, O, N, F and combinations thereof to SiN or SiC.

FIG. 5A is a graph showing a combination state of SiN obtained from a deposition process that a bias is not applied to a substrate in a method of manufacturing a semiconductor device according to exemplary embodiments of the present invention. FIG. 5B is a graph showing a combination state of SiN obtained from a deposition process that a bias is applied to a substrate in a method of manufacturing a semiconductor device according to exemplary embodiments of the present invention. Here, the process may be a deposition process using PIIID.

Graphs qualitatively analyze a combination state of SiN by measuring absorption of various wavelengths of infrared radiation using a well known Fourier Transform Infrared Spectroscopy (FT-IR). A horizontal axis of the graph represents a wave number of cm⁻¹ unit and a vertical axis represents an absorption ratio as a relative numerical value.

Referring to FIG. 5A, when a bias is not applied to a substrate, N—H peak is relatively higher than Si—N peak and this means that a large number of hydrogen may be included in the N—H combination (i.e., SiN). Referring to FIG. 5B, when a bias is applied to a substrate, N—H peak becomes very low and a peak of SiN becomes relatively high compared with a peak of SiN of FIG. 5A. That is, if depositing SiN using PIIID under the condition that a bias is applied to a substrate, almost complete SiN combination may be formed.

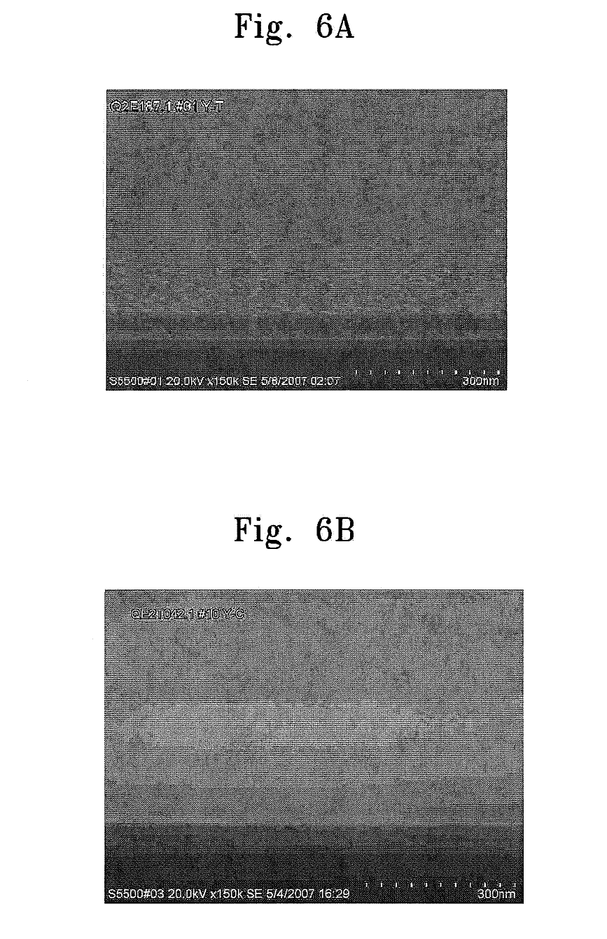

FIG. 6A is a microphotograph of SiN obtained from a PIIID process that a bias is not applied to a substrate in a method of manufacturing a semiconductor device according to a first exemplary embodiment of the present invention. FIG. 6B is a microphotograph of SiN obtained from a PIIID process that a bias is applied to a substrate in a method of manufacturing a semiconductor device according to a first exemplary embodiment of the present invention.

When a bias is not applied to a substrate, SiN is formed to have a rough surface in some degree as shown in FIG. 6A. That means that SiN is deposited to have a structure which is relatively not fine compared with when a bias is applied to a substrate. If a bias is applied to a substrate, SiN may be formed to have a very slippery surface of very fine structure.

As an example of a process applying a bias to deposit SiN, reaction gases of SiH₄, a bias condition of about 1 to about 5 killivolts (kV) and a deposition pressure of about 15 to about 100 milli-torr (mT) may be adopted. A ratio of a supplying speed of SiH₄ to a supplying speed of N₂ may become about 1:10 to about 1:20. Plasma is ignited using argon (Ar) plasma, a surface of a substrate is preprocessed to reform the surface of the substrate, reaction gases of SiH₄ and nitrogen (N₂) are injected not applying a bias to the substrate, and SiN may be deposited by applying a bias to the substrate. Selectively, a deposition refrigerant, for example, helium (He), is further provided to prevent a temperature of a substrate from excessively increasing.

Table 1 below represents a condition of SiN deposition. In the table 1, a supply of a reaction gas and a bias are represented as a ratio. FIG. 6B represents SiN deposited under the condition that a bias is about 2×, that is, under the condition of setting 3.

TABLE 1

| | reaction gas | | deposition | | | | Growth | roughness |
|---|---|---|---|---|---|---|---|---|
| | supply (sccm) | | pressure | Bias | Power | Deposition | rate | Ra |
| setting | SiH₄ | N₂ | (mT) | (kV) | (W) | time (s) | (Å/sec) | (nm) |
| 1 | 1X | 20X | 30 | 0 | 500 | 100 | 5.80 | 0.69 |
| 2 | 1X | 20X | 30 | 1X | 500 | 100 | 4.59 | 0.71 |
| 3 | 1X | 20X | 30 | 2X | 500 | 100 | 4.72 | 0.18 |

Referring to FIG. 1D, a first high concentration impurity is implanted into the substrate 100. For example, AsH₄ is adopted as the first high concentration impurity to dope the substrate 100 with N⁺. In this case, the first mask layer 150 may prevent impurities from being implanted into the second active region 132. The first sacrifice layer 152 formed on both sidewalls of the first gate pattern 110 functions as a first disposable spacer 152a which will be removed in the subsequent process. The first disposable spacer 152a may prevent impurities from being implanted into a portion of the first LDD 112 adjacent to a position under the both sidewalls of the first gate pattern 110. The first sacrifice layer 152 formed on both sidewalls of the first mask layer 150 may function as another disposable spacer 152b. The disposable spacer 152b may prevent impurities from being implanted into the first LDD 112 under the disposable spacer 152b. The first hard mask layer 107 may prevent impurities from being implanted into the first gate electrode 106.

First high concentration impurities are selectively implanted into the first active region 102 adjacent to both sidewalls of the first gate pattern 110 to form the first deep source/drain 114. The area of the first deep source/drain 114 is smaller than the first LDD 112 and the depth of the first deep source/drain 114 is greater than the first LDD 112. As a result, a first junction region 116 comprised of the first LDD 112 doped with N⁻ and the first deep source/drain 114 doped with N⁺ is formed. As the distance between the first deep source/drains 114 is in proportion to a thickness of the first sacrifice layer 152, the distance between the first deep source/drains 114 becomes short as the thickness of the first sacrifice layer 152 is small.

An ion doping using an ion implantation or plasma doping using PIIID may be adopted as the first high concentration impurity doping to form the first deep source/drain 114. It is preferable to adopt plasma doping using PIIID to form the first deep source/drain 114. As the first LDD 112, the first sacrifice layer 152 and the first deep source/drain 114 may be formed in-situ by adopting plasma doping using PIID, a more simplified process can be obtained. The condition of the plasma doping for forming the first deep source/drain 114 may be different from the condition of the plasma doping for forming the first LDD 112. For example, the first deep source/drain 114 may be deeply formed compared with the first LDD 112 by adopting a high doping energy.

Referring to FIG. 1E, the first sacrifice layer 152 is removed. Thus, the first gate pattern 110 and the first active region 102 including the first junction region 116 of LDD structure are exposed. The first sacrifice layer 152 may be removed using, for example, a wet etching. Alternatively, the first sacrifice layer 152 may be removed by, for example, conformally etching SiN using PIIID where CF4 is used as an etchant. When adopting a plasma etching process using PIIID, formations of the first LDD 112, the first sacrifice layer 152 and the first deep source/drain 114, and the removal of the first sacrifice layer 152 may be performed in-situ.

Referring to FIG. 1F, the first mask layer 150 is removed. The first mask layer 150 may be removed using, for example, an etching process. The second active region 132 on which the second gate pattern 140 is formed is exposed by removing the first mask layer 150.

Referring to FIG. 1G, a second mask layer 160 is formed in a similar manner described in FIG. 1B. The second mask layer 160 covers the first active region 102 and not cover the second active region 132. The second mask layer 160 may be formed by, for example, coating a photoresist on the entire surface of the substrate 100 and selectively removing a portion covering the second active region 132.

After that, as a second low concentration doping, a low concentration impurity is implanted into the second active region 132 adjacent to both sidewalls of the second gate pattern 140 using the second mask layer 160 as a mask to form a second LDD 142. The second LDD 142 may be doped with, for example, P⁻ by adopting boron trifluoride (BF₃) as an impurity. The second mask layer 160 may prevent impurities from being implanted into the first active region 102 and the second hard mask layer 137 may prevent impurities from being implanted into the second gate electrode 136. The second low concentration impurity process may be performed using, for example, plasma doping using PIIID.

Referring to FIG. 1H, SiN is deposited on the entire surface of the substrate 100 using a plasma deposition using PIIID under the condition that a bias is applied to the substrate 100 without removing the second mask layer 160. Thus, a second sacrifice layer 162 comprised of SiN having a flat and fine structure is formed.

Referring to FIG. 1I, as a second high concentration impurity doping, a high concentration impurity is implanted into the substrate 100 by adopting plasma doping using PIIID. For example, the substrate 100 may be doped with P⁺ by adopting BF₃ as an impurity. The second mask layer 160 may prevent impurities from being implanted into the first active region 102. A portion 162a of the second sacrifice layer 162 functions as a second disposable spacer and may prevent impurities from being implanted into a portion of the second LDD 142 adjacent to under both sidewalls of the second gate pattern 140. The second sacrifice layer 162 formed on both sidewalls of the second mask layer 160 may function as another disposable spacer 162b. The disposable spacer 162b may prevent impurities from being implanted into the second LDD 142 under the disposable spacer 162b. The second hard mask layer 137 may prevent impurities from being implanted into the second gate electrode 136.

Second high concentration impurities are selectively implanted into the second active region 132 adjacent to both sidewalls of the second gate pattern 140 to form the second deep source/drain 144. The area of the second deep source/drain 144 is smaller than the second LDD 142 and the depth of the second deep source/drain 144 is greater than the second LDD 142. As a result, a second junction region 146 comprised of the second LDD 142 doped with P⁻ and the second deep source/drain 144 doped with P⁺ is formed. As the second LDD 142, the second sacrifice layer 162 and the second deep source/drain 144 may be formed in-situ by adopting plasma doping using PIID, a more simplified process can be obtained.

The distance between the second source/drains 144 is also in proportion to the thickness of the second sacrifice layer 162. Thus, if the first sacrifice layer 152 is formed to be thin, the distance between the first deep source/drains 114 may become short and if the second sacrifice layer 162 is formed to be thick, the distance between the second deep source/drains 144 may become long. If the distance between the first deep source/drains 114 is short, integration becomes high, and if the distance between the first deep source/drains 114 is long, a characteristic of a short channel effect can be improved. The case of the second deep source/drain 144 is similar to the case of the first deep source/drain 114.

Referring to FIG. 1J, the second sacrifice layer 162 is removed. Thus, the second gate pattern 140 and the second active region 132 including the second junction region 146 of LDD structure are exposed. The second sacrifice layer 162 may be removed using, for example, a wet etching. Alternatively, the second sacrifice layer 162 may be removed by, for example, an etching using PIIID. When adopting a plasma etching process using PIIID, formations of the second LDD 142, the second sacrifice layer 162 and the second deep source/drain 144, and a removal of the second sacrifice layer 162 may be performed in-situ.

Referring to FIG. 1K, the second mask layer 160 is removed using, for example, an ashing process. The first gate pattern 110 and the first active region 102 in which the first junction region 116 of LDD structure is formed are exposed by removing the second mask layer 160. The first hard mask layer 107 and the second hard mask layer 137 may be selectively removed. Alternatively, the first hard mask layer 107 and the second hard mask layer 137 may remain on the first gate electrode 106 and the second gate electrode 136, respectively

After that, a first spacer 118 is formed on both sidewalls of the first gate pattern 110 and a second spacer 148 is formed on both sidewalls of the second gate pattern 140. As the spacers 118 and 148 are not removed unlike the disposable spacers 152a and 162a, they may be designated as a permanent spacer. The permanent spacers 118 and 148 may be formed of, for example, silicon oxide (SiO₂) or silicon nitride (SiN). Generally, silicon oxide (SiO₂) is deposited on the substrate 100 to form an interlayer insulating layer. If the permanent spacers 118 and 148 are formed of silicon nitride (SiN) having a superior etching selectivity compared to silicon oxide (SiO₂), a contact hole penetrating the insulating layer formed of silicon oxide (SiO₂) to expose the junction regions 116 and 46 may be formed to be self aligned.

By a series processes described above, a semiconductor device 10 where the first active region 102 including a NMOS field effect transistor 111 and the second active region 132 including a PMOS field effect transistor 141 are formed may be embodied. One of the first active region 102 and the second active region 132 may be included in a cell region and the other may be included in a peripheral region. For example, the first active region 102 is included in the cell region and the second active region 132 is included in the peripheral region. In another example, all the first and second active regions 102 and 132 may be included to the peripheral region.

### Second Exemplary Embodiment

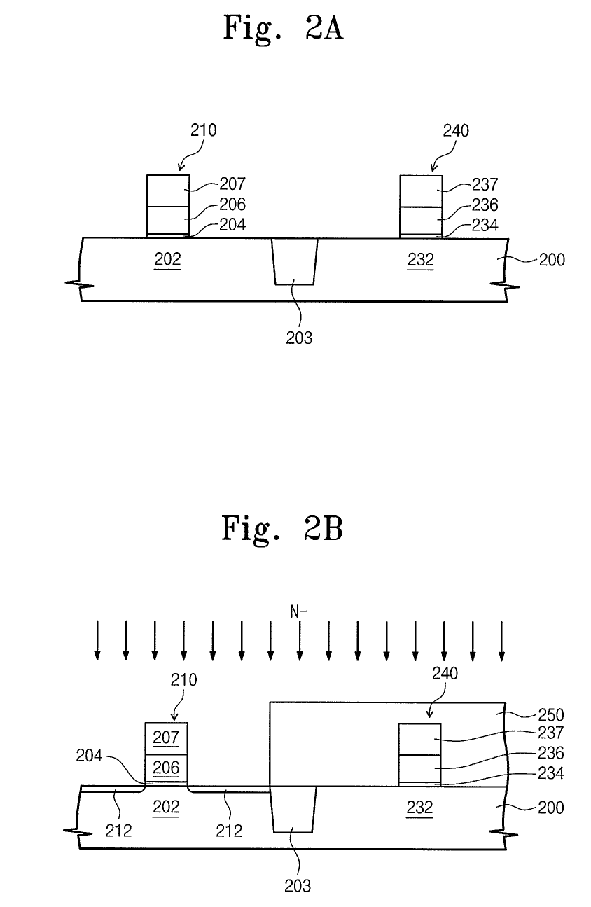

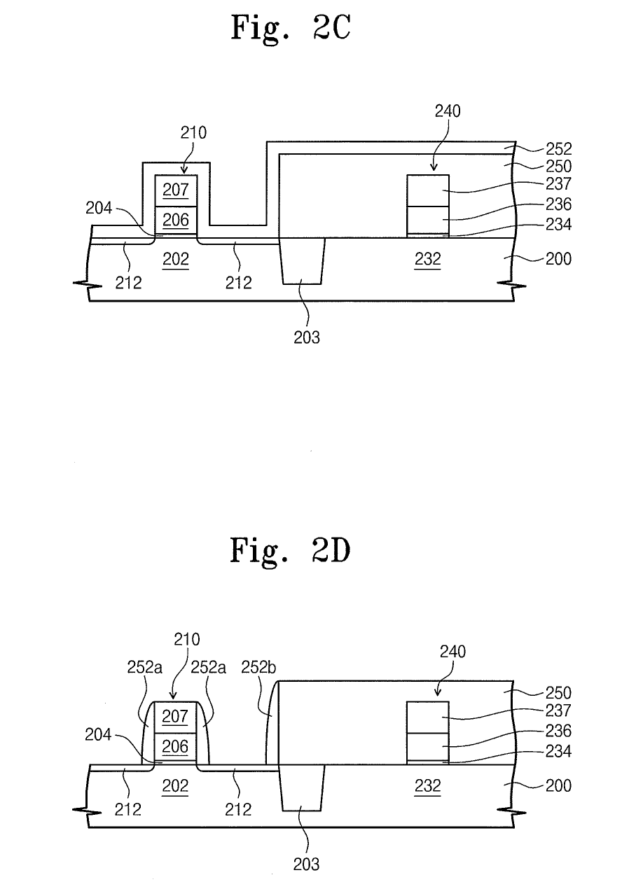

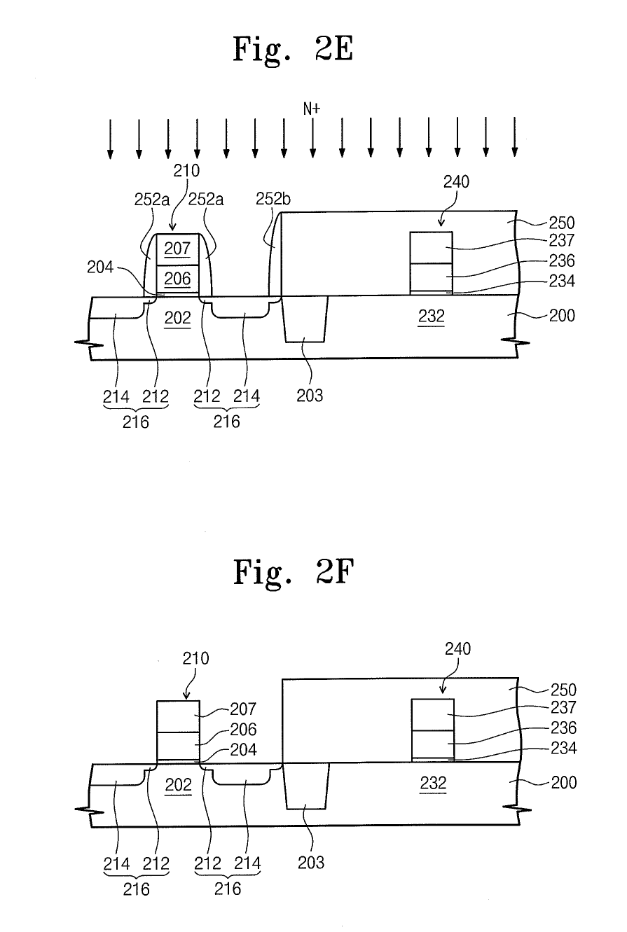

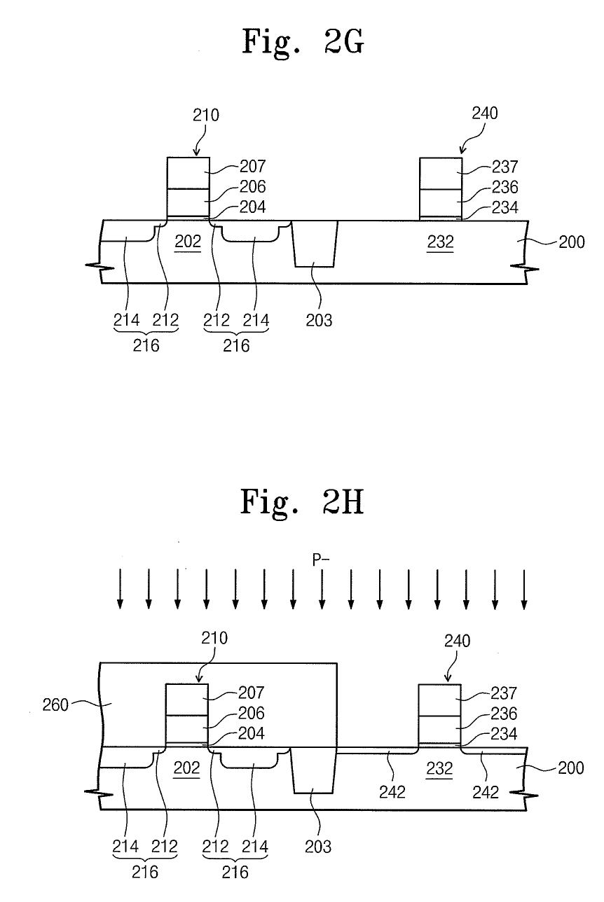

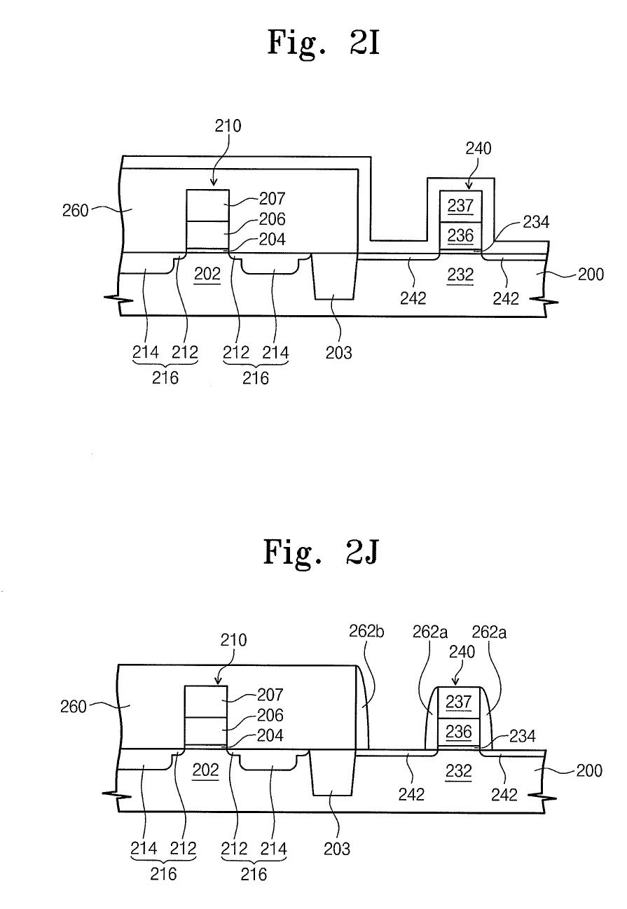

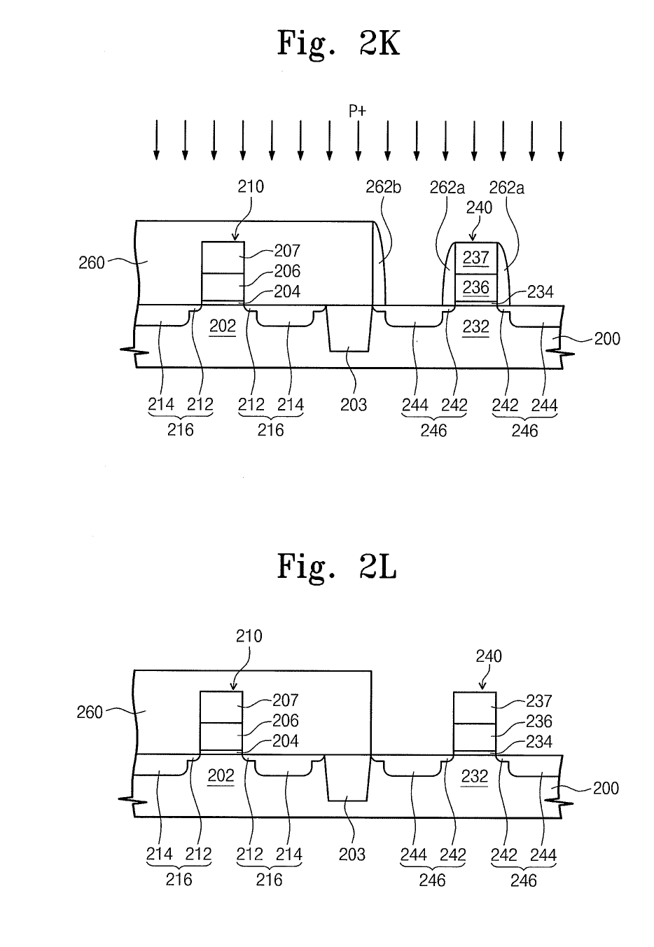

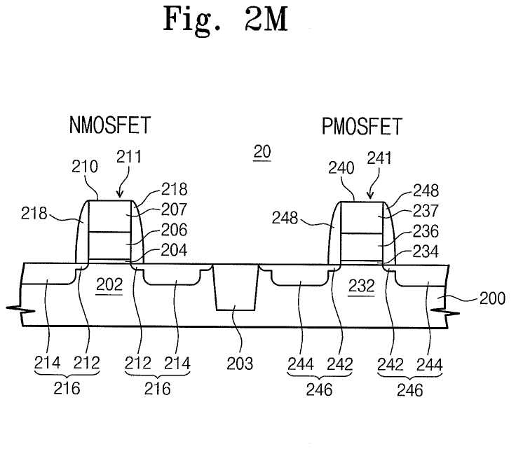

FIGS. 2A through 2M are cross sectional views of process steps illustrating a method of manufacturing a semiconductor device according to a second exemplary embodiment of the present invention. As the second exemplary embodiment is similar to the first exemplary embodiment, description of common features already discussed in the first embodiment will be omitted for brevity, while any new or different features will be described in further detail below.

Referring to FIG. 2A, a substrate 200 including a first active region 202 of P conductivity type and a second active region 232 of N conductivity type is provided. The first active region 202 and the second active region 232 are divided by a device isolation layer 203. A first gate pattern 210 including a first gate insulating layer 204, a first gate electrode 206 and a first hard mask layer 207 that are sequentially stacked is formed on the first active region 202. In addition, a second gate pattern 240 including a second gate insulating layer 234, a second gate electrode 236 and a second hard mask layer 237 that are sequentially stacked is formed on the second active region 232.

Referring to FIG. 2B, a photoresist is coated and selectively removed to form a first mask layer 250 which exposes the first active region 202 and covers the second active region 232. After that, as a first low concentration doping, a low concentration impurity is implanted into the substrate 200. The first low concentration doping may adopt plasma doping using, for example, PIIID adopting AsH₄ as an impurity. A first LDD 212 doped with N− is formed in the first active region 202 under both sidewalls of the first gate pattern 210 by the first low concentration doping.

Referring to FIG. 2C, a first sacrifice layer 252 is formed on the entire surface of the substrate 200 without removing the first mask layer 250. The first sacrifice layer 252 may be formed on the substrate 200 by, for example, depositing SiN at a low temperature under the condition that a bias is applied to the substrate 200.

After forming the first sacrifice layer 252, a first deep source/drain may be formed by, for example, performing plasma doping using PIIID as described in FIG. 1B. A projection point (Rp) is formed on a surface of the substrate 200 during plasma doping using PIIID. However, as the first sacrifice layer 252 is covered on the first LDD 212, it may be difficult to form a deep source/drain having a great depth. Thus, as will be described referring to FIG. 2D, a doping process for forming a deep source/drain may be readily performed by, for example, selectively removing the first sacrifice layer 252 through an etching process.

Referring to FIG. 2D, the first sacrifice layer 252 is anisotropically etched to form a first disposable spacer 252a on both sidewalls of the first gate pattern 210. Another disposable spacer 252b may be formed on a sidewall of the first mask layer 250. Plasma etching using PIIID may be adopted as an anisotropic etching. In this case, a bias is applied to the substrate 200. For example, carbon tetrafluoride (CF₄) may be adopted as an etchant of plasma etching using PIIID.

Referring to FIG. 2E, as a first high concentration impurity doping, a high concentration impurity, for example AsH₄, is implanted into the substrate 200 to form a first deep source/drain 214. As a result, a first junction region 216 comprised of the first LDD 212 doped with N⁻ and the first deep source/drain 214 doped with N⁺ is formed in the first active region 202 adjacent to both sidewalls of the first gate pattern 210.

As the first sacrifice layer 252 is removed on the first LDD 212, the first high concentration impurity doping may be readily performed. As the first LDD 212, the first sacrifice layer 252, the first disposable spacer 252a and the first deep source/drain 214 may be formed in-situ by adopting plasma doping using PIID, a more simplified process can be obtained.

Referring to FIG. 2F, the first disposable spacer 252a is removed. The first disposable spacer 252a may be removed using, for example, a wet etching. Alternatively, the first disposable spacer 252a may be removed by, for example, etching SiN using PIIID where CF₄ is used as an etchant. The disposable spacer 252b formed on sidewall of the first mask layer 250 may be removed when the first disposable spacer 252a is removed.

When an etching process using PIIID is adopted, formations of the first LDD 212, the first sacrifice layer 252, the first disposable spacer 252a and the first deep source/drain 214, and the removal of first disposable spacer 252b may be performed in-situ.

Referring to FIG. 2G, the first mask layer 250 is removed. The first mask layer 250 may be removed using, for example, ashing process. The second active region 232 on which second gate pattern 240 is formed is exposed by removing the second mask layer 150.

Referring to FIG. 2H, a photoresist is coated and selectively removed to form a second mask layer 260 which covers the first active region 202 and does not cover the second active region 232. After that, as a second low concentration doping, a low concentration impurity is implanted into the second active region 232 adjacent to both sidewalls of the second gate pattern 240 using the second mask layer 260 as a mask to form a second LDD 242. The second LDD 242 may be doped with, for example, P⁻ by adopting BF₃ as an impurity. The second low concentration impurity process may be performed using, for example, plasma doping using PIIID.

Referring to FIG. 2I, SiN is deposited on the entire surface of the substrate using plasma deposition using PIIID under the condition that a bias is applied to the substrate 200 without removing the second mask layer 260. Thus, a second sacrifice layer 262 comprised of SiN having a flat and fine structure is formed.

Referring to FIG. 2J, the second sacrifice layer 262 is anisotropically etched to form a second disposable spacer 262a on both sidewalls of the second gate pattern 240. Another disposable spacer 262b may be formed on a sidewall of the second mask layer 260. A plasma etching using, for example, PIIID may be adopted as an anisotropic etching. For example, CF₄ may be adopted as an etchant of a plasma etching using PIIID.

Referring to FIG. 2K, as a second high concentration impurity doping, a high concentration impurity, for example AsH₄, is implanted into the substrate 200 to form a second deep source/drain 244. As a result, a second junction region 246 comprised of the second LDD 242 doped with P⁻ and the second deep source/drain 244 doped with P⁺ is formed in the second active region 232 adjacent to both sidewalls of the second gate pattern 240.

As the second LDD 242, the second sacrifice layer 262, the second disposable spacer 262a and the second deep source/drain 244 may be formed in-situ by adopting plasma doping using PIID as the second high concentration impurity doping, a process can be simplified.

Referring to FIG. 2L, the second disposable spacer 262a is removed. The second disposable spacer 262a may be removed using, for example, a wet etching. Alternatively, the second disposable spacer 262a may be removed using, for example, PIIID where CF₄ is used as an etchant. The disposable spacer 262b formed on sidewall of the second mask layer 260 may be removed when the second disposable spacer 262a is removed. When adopting an etching process using PIIID, formations of the second LDD 242, the second sacrifice layer 262 and the second deep source/drain 244, and the removal of the second disposable spacer 262b may be performed in-situ.

Referring to FIG. 2M, the second mask layer 260 is removed by, for example, an ashing process. After that, a first permanent spacer 218 is formed on both sidewalls of the first gate pattern 210 and a second permanent spacer 248 is formed on both sidewalls of the second gate pattern 240. As a result, a semiconductor device 20 including an NMOS field effect transistor 211 formed on the first active region 202 and a PMOS field effect transistor 241 formed on the second active region 232 may be embodied.

The second embodiment has characteristics different from the first embodiment from the viewpoint that plasma doping for forming the deep source/drain 214 and 244 may be readily performed by removing a portion of the sacrifice layers 252 and 262 to expose the active regions 202 and 232.

### Third Exemplary Embodiment

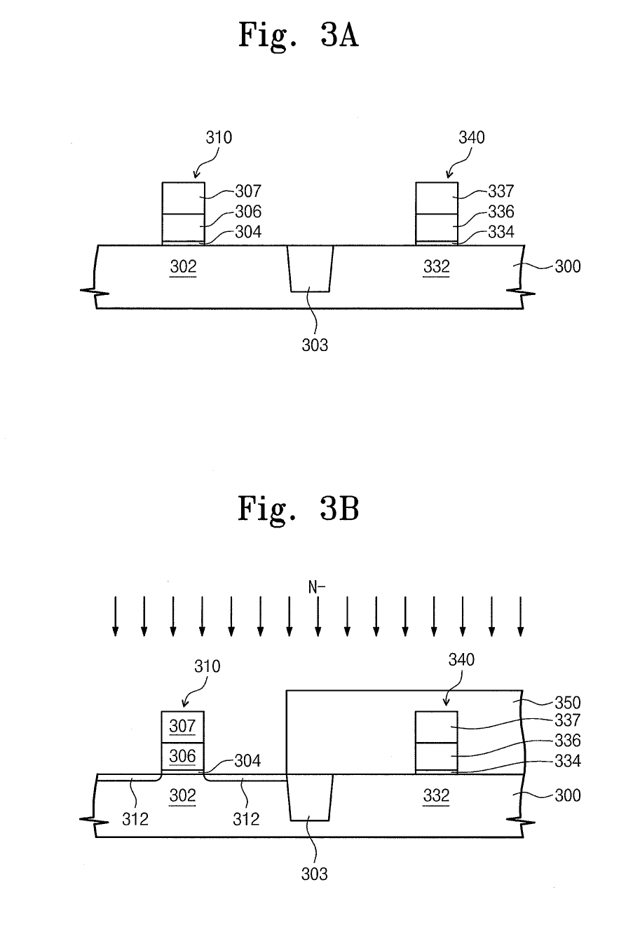

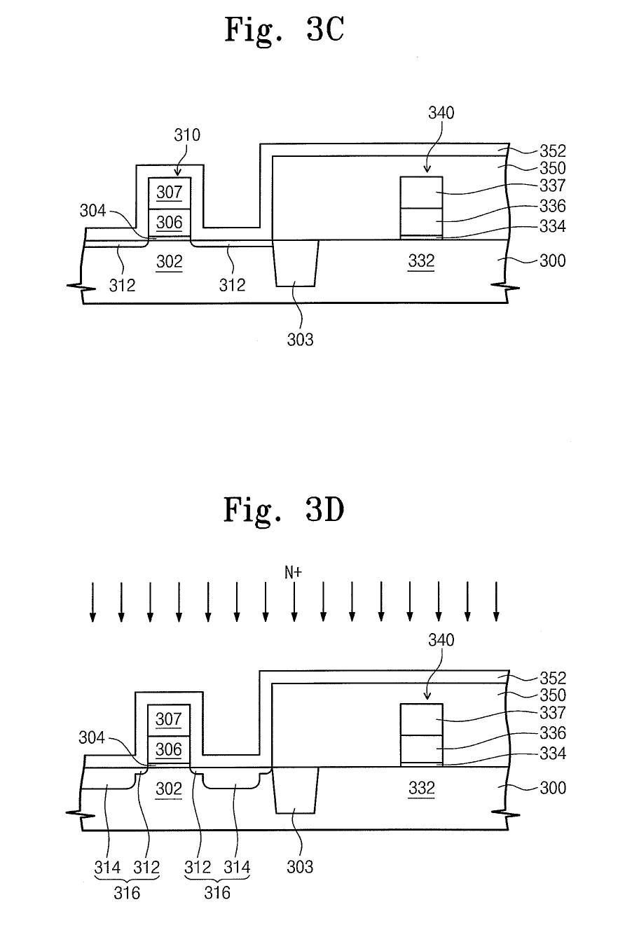

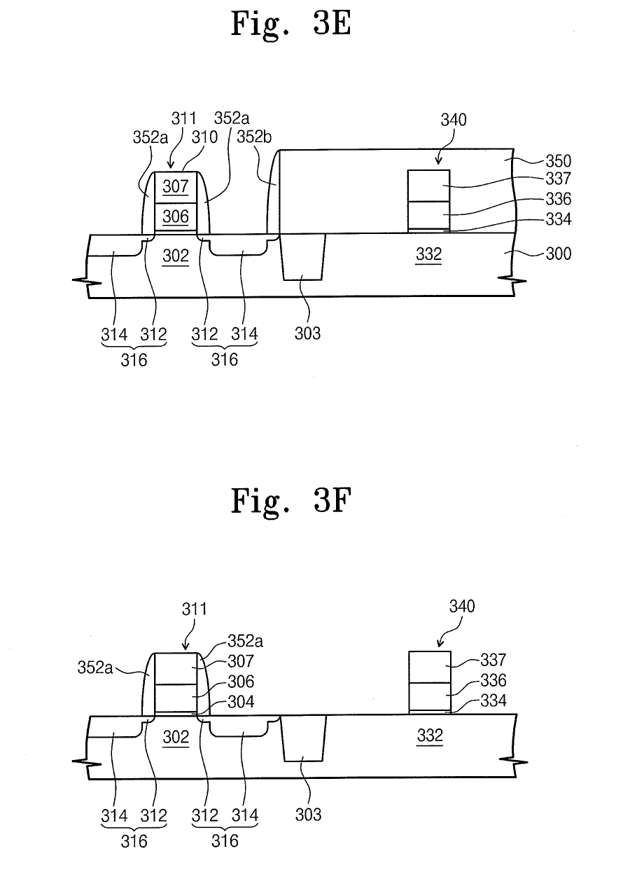

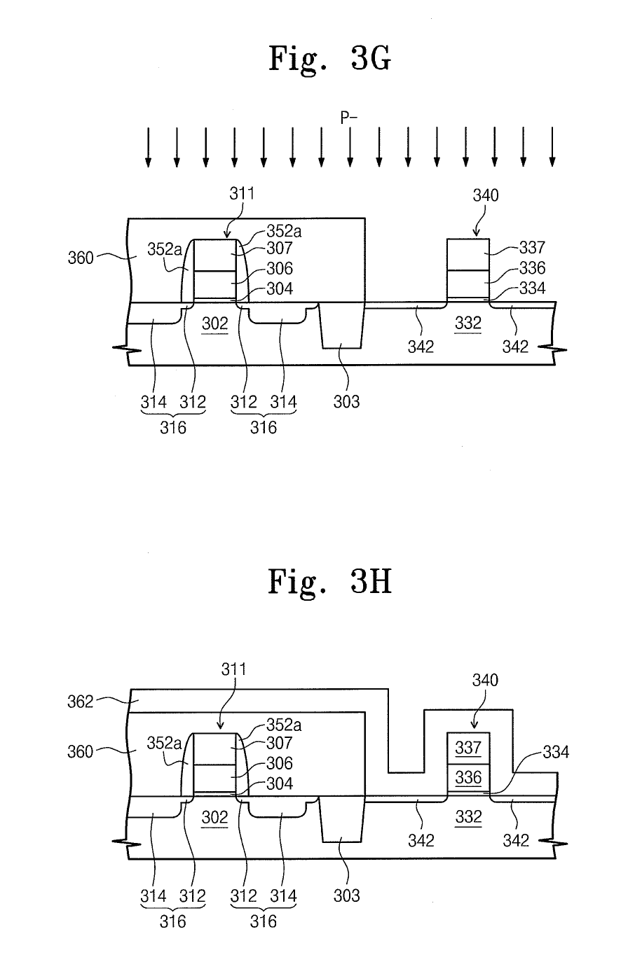

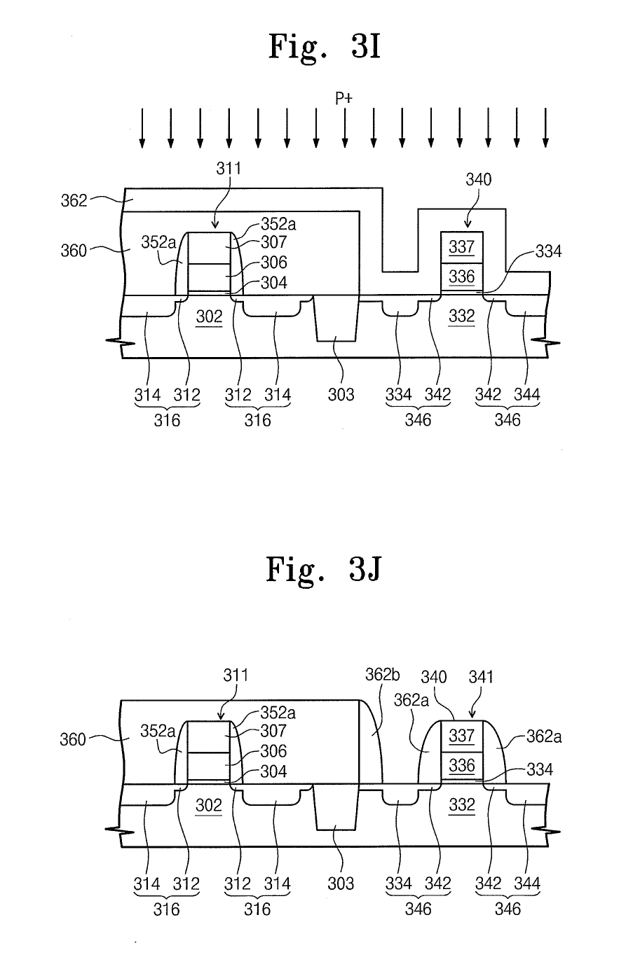

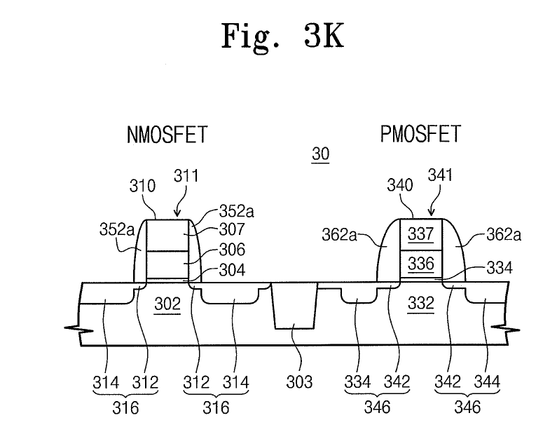

FIGS. 3A through 3K are cross sectional views of process steps illustrating a method of manufacturing a semiconductor device according to a third exemplary embodiment of the present invention. As the third exemplary embodiment is similar to the second exemplary embodiment, description of common features already discussed in the second exemplary embodiment will be omitted for brevity, while any new or different features will be described in further detail below.

Referring to FIG. 3A, a first gate pattern 310 is formed on a first active region 302 of a substrate 300 and a second gate pattern 340 is formed on a second active region 332 of a substrate 300. The active regions 302 and 332 are divided by a device isolation layer 303. The first gate pattern 310 may include a first gate insulating layer 304, a first gate electrode 306 and a first hard mask layer 307 that are sequentially stacked and the second gate pattern 340 may include a second gate insulating layer 334, a second gate electrode 336 and a second hard mask layer 337 that are sequentially stacked.

Referring to FIG. 3B, a first mask layer 350 selectively covering the second active region 332 is formed and as a first low concentration impurity doping, plasma doping using PIIID is adopted to implant a low concentration impurity, for example AsH₄, into the first active region 302. Therefore, a first LDD 312 doped with N− is formed in the first active region 302 adjacent to both sidewalls of the first gate pattern 310.

Referring to FIG. 3C, SiN is deposited on the entire surface of the substrate 300 using PIIID under the condition that a bias is applied to the substrate 300. A first sacrifice layer 352 which covers the first gate pattern 310 and a first LDD 312 at the first active region 302 and covers the first mask layer 350 at the second active region 332 is formed by depositing SiN.

Referring to FIG. 3D, as a first high concentration impurity, plasma doping using PIIID is adopted to implant a high impurity, for example AsH₄, into the substrate 300. When doping the first high concentration impurity, the first sacrifice layer 352 may prevent impurities from being implanted into a portion of the first LDD 312 adjacent to both sidewalls of the first gate pattern 310 because the first sacrifice layer 352 functions as a spacer. Thus, a first deep source/drain 314 is formed to constitute a first junction region 316 of LDD structure. Here, an area of the first deep source/drain 314 is smaller than an area of the first LDD 312 and a depth of the first deep source/drain 314 is greater than a depth of the first LDD 312.

Referring to FIG. 3E, a portion of the first sacrifice layer 352 is removed by a plasma etching using PIIID to form a first spacer 352a on both sidewalls of the first gate pattern 310. When the first spacer 352a is formed, another spacer 352b may also be formed on a sidewall of the first mask layer 350. The first spacer 352a may be referred to as a permanent spacer not removed by a subsequent process and remains on the sidewalls of the first gate pattern 310 unlike the first and second exemplary embodiments.

In the third exemplary embodiment, an NMOS field effect transistor 311 may be formed before a PMOS field effect transistor (341 of FIG. 3J) is formed. The first LDD 312, the first sacrifice layer 352, the first deep source/drain 314 and the first spacer 352a may be formed in-situ by using, for example, PIIID.

Referring to FIG. 3F, the first mask layer 350 and the spacer 352b are removed to expose the second active region 332 including the second gate pattern 340. The first mask layer 350 and the spacer 352b may be simultaneously removed or sequentially removed. For example, the first mask layer 350 may be removed using an ashing process and the spacer 352b may be removed using a wet etching or a dry etching. When the first mask layer 350 and the spacer 352b are removed, a protection layer should be formed on the first active region 302 so that an NMOS field effect transistor 311 is not removed.

Referring to FIG. 3G, a second mask layer 360 selectively covering the first active region 302 is formed and as a second low concentration impurity doping, a low concentration impurity, for example BF3, is implanted into the second active region 332 by adopting plasma doping using, for example, PIIID. As a result, a second LDD 342 doped with P⁻ conductivity type is formed on the second active region 332 adjacent to both sidewalls of the second gate pattern 340.

Referring to FIG. 3H, SiN is deposited on the entire surface of the substrate 300 using PIIID under the condition that a bias is applied to the substrate 300. A second sacrifice layer 362 which covers the second gate pattern 340 and the second LDD 342 at the second active region 332 and covers the second mask layer 360 at the first active region 302 is formed by a deposition of SiN. A deposition condition of SiN is properly controlled so that the second sacrifice layer 362 is formed to be thicker than the first sacrifice layer 352.

Referring to FIG. 3I, as a high concentration impurity doping, a high concentration impurity, for example BF₃, is implanted into the substrate 300 by adopting plasma doping using PIIID. When the second high concentration impurity is doped, the second sacrifice layer 362 may prevent impurities from being implanted into a portion of the second LDD 342 adjacent to both sidewalls of the second gate pattern 340 because the second sacrifice layer 362 functions as a spacer. Thus, a second deep source/drain 344 doped with P⁺ is formed to constitute a second junction region 346 of LDD structure. The area of the second deep source/drain 344 is smaller than the area of the second LDD 342 and the depth of the second deep source/drain 344 is greater than the depth of the second LDD 342.

As the second sacrifice 362 is formed to be thicker than the first sacrifice layer 352, a cutoff range of an impurity is great. This means that an impurity of the second high concentration impurity doping is implanted into an area smaller than the first high concentration impurity doping. The second deep source/drain 344 is formed to have an area smaller than the first deep source/drain 314, so that the distance between the second deep source/drains 344 becomes great compared with the distance between the first deep source/drains 314. The sacrifice layers 352 and 362 having different thicknesses are formed, so that the junction regions 316 and 346 having different distances may be formed.

Referring to FIG. 3J, a portion of the second sacrifice layer 362 is removed using, for example, a plasma etching using PIIID to form a second permanent spacer 362a on both sidewalls of the second gate pattern 340. A P channel metal oxide semiconductor (PMOS) field effect transistor 341 is formed on the second active region 332. As the second sacrifice layer 362 is formed to be thicker than the first sacrifice layer 352, the second permanent spacer 362a is thicker than the first permanent spacer 352a. When the second permanent spacer 362a is formed, another spacer 362b may be formed on a sidewall of the second mask layer 360. The second LDD 342, the second sacrifice layer 362, the second deep source/drain 344 and the second spacer 362a may be formed in-situ by using, for example, PIIID.

Referring to FIG. 3K, the second mask layer 360 and the spacer 362b are removed. A semiconductor device 30 including an N channel metal oxide semiconductor (NMOS) field effect transistor 311 having the thin first permanent spacer 352a and the first junction region 316 of a short distance formed on the first active region 302, and a PMOS field effect transistor 341 having the thick second permanent spacer 362a and the second junction region 346 of long distance formed on the second active region 332 may be embodied. New permanent spacers may be formed by removing the permanent spacers 352a and 362a. Alternatively, other permanent spacers may be further formed without removing the permanent spacers 352a and 362a.

The NMOS field effect transistor 311 is mainly used in a cell region and the PMOS field effect transistor 341 is mainly used in a peripheral region. The PMOS field effect transistor 341 is well known to be weak to a short channel effect compared with the NMOS field effect transistor 311. In the third exemplary embodiment, distances between the deep source/drains 316 and 346 can be controlled by, for example, controlling thicknesses of the sacrifice layers 352 and 362. Thus, the first junction region 316 of the NMOS field effect transistor 311 may be formed to have a short distance and the second junction 346 of the PMOS field effect transistor 341 may be formed to have a long distance. In the third exemplary embodiment, integration of NMOS field effect transistor 311 and a short channel effect of the PMOS field effect transistor 341 may be simultaneously improved.

In another example, the junction regions 316 and 346 having different distances may be formed by, for example, reducing the width of a gate of the NMOS field effect transistor 311 and enlarging the width of a gate of the PMOS field effect transistor 341 to satisfy improvements of an integration and a short channel effect characteristic at the same time. However, as the width of a gate is different, there may be difficulties in that the design rule or a condition of a mask process should be changed or the design rule may not be satisfied. In the third exemplary embodiment, as the width of a gate of the NMOS field effect transistor 311 and a gate of the PMOS field effect transistor 341 are equal to each other and can be formed as minute as possible, the design rule may be satisfied without changing a condition of the mask process and an integration and a short channel effect characteristic can be simultaneously improved.

### Fourth Exemplary Embodiment

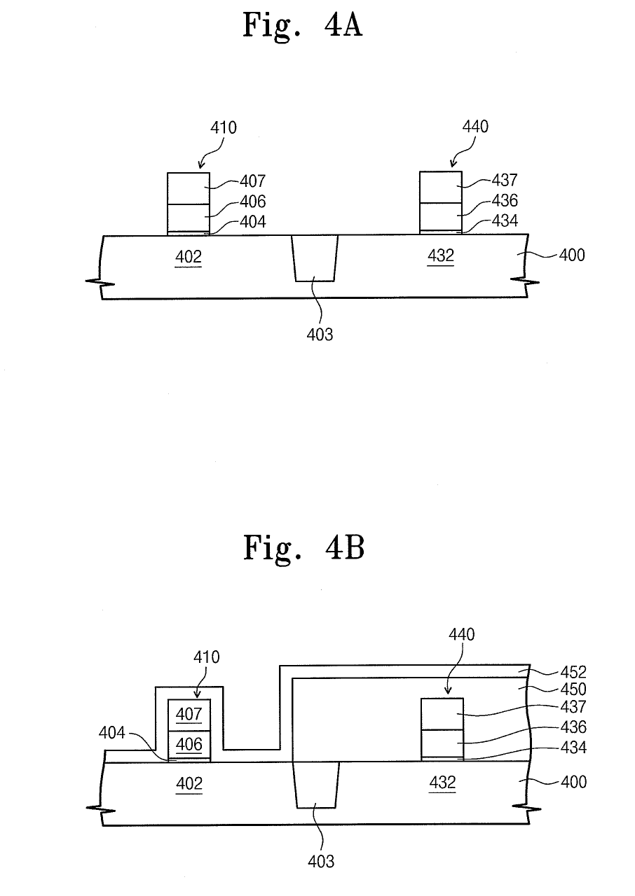

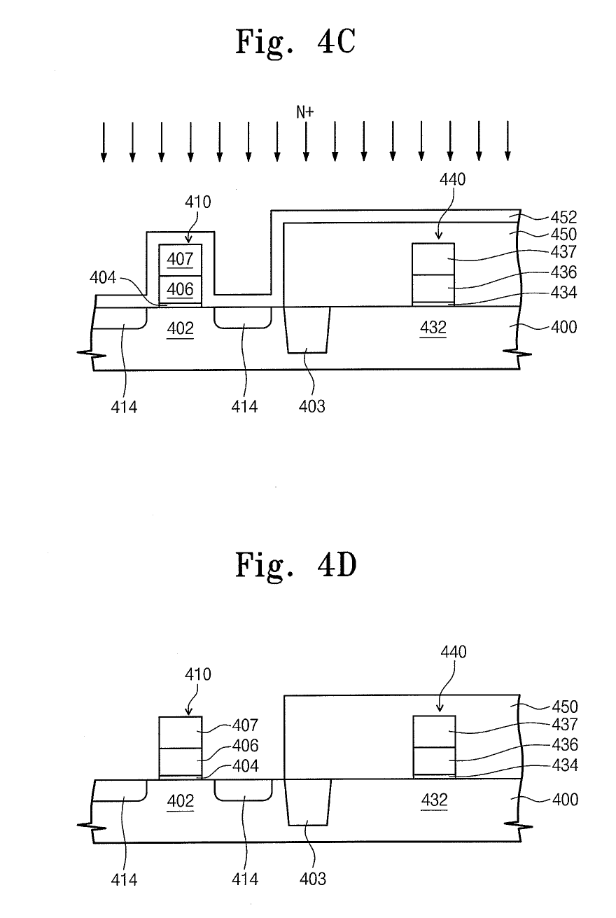

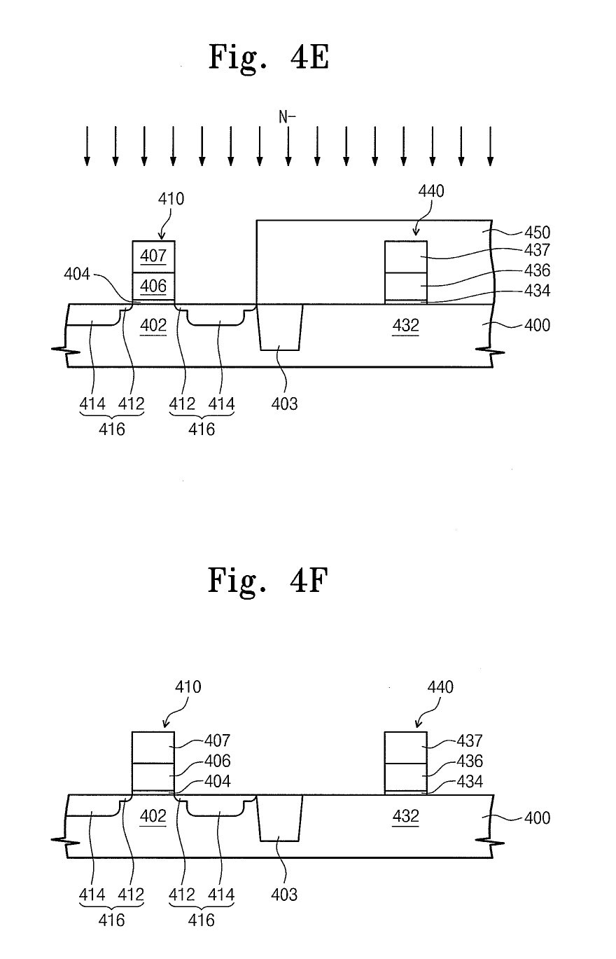

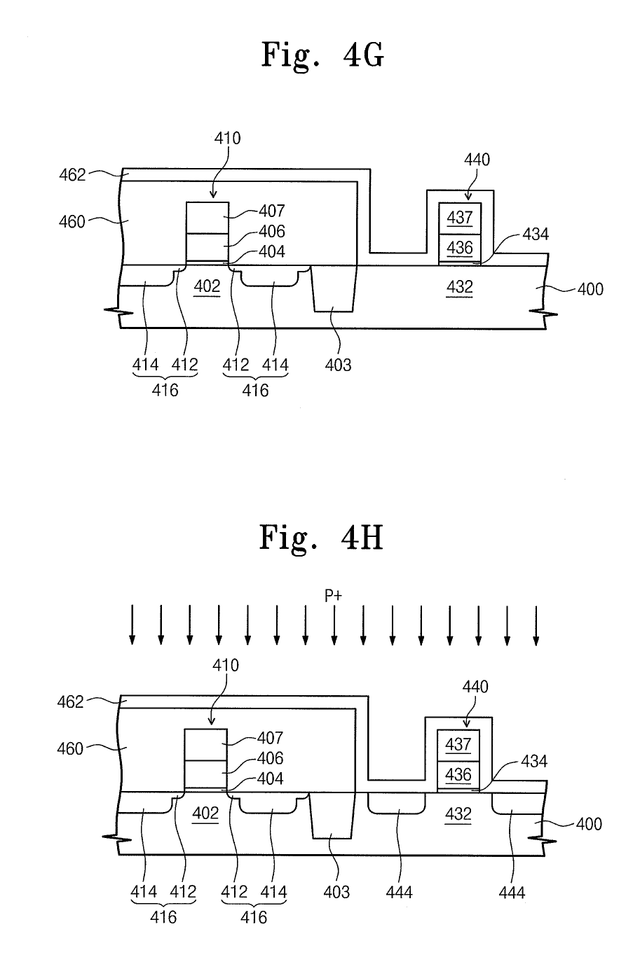

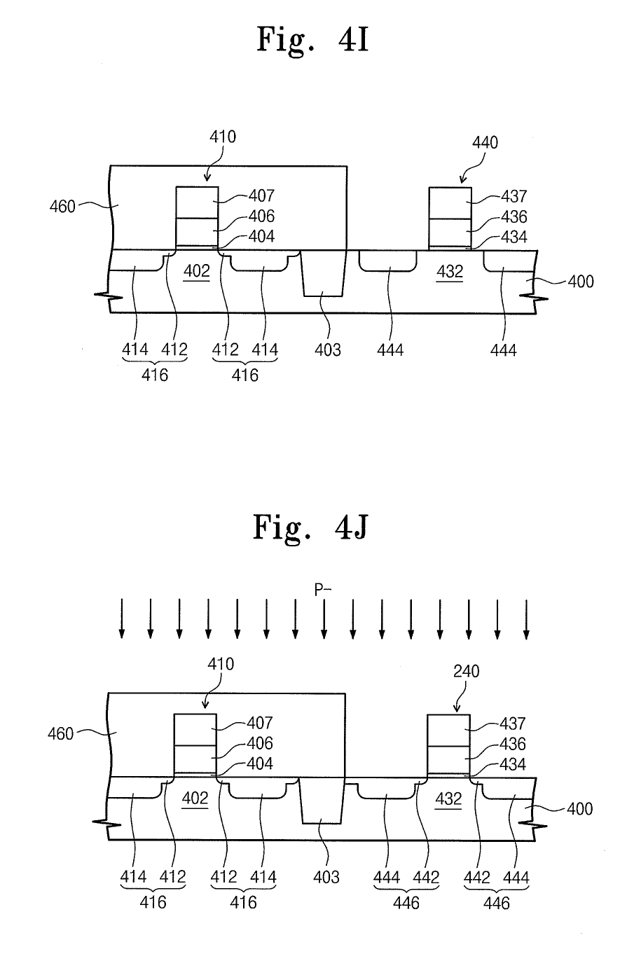

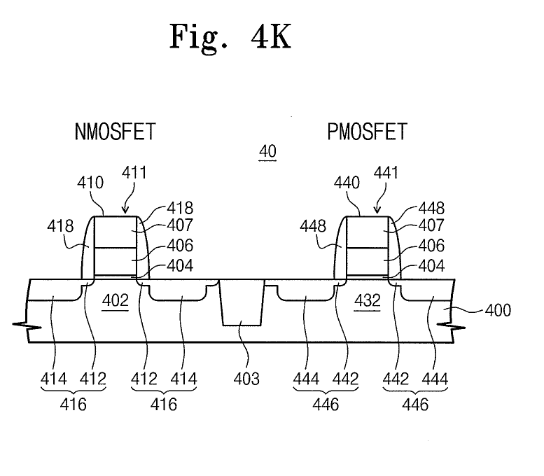

FIGS. 4A through 4K are cross sectional views of process steps illustrating a method of manufacturing a semiconductor device according to a fourth exemplary embodiment of the present invention. As the fourth exemplary embodiment is similar to the first exemplary embodiment to third exemplary embodiment, description of common features already discussed in the first exemplary embodiment to the third exemplary embodiment will be omitted for brevity, while any new or different features will be described in further detail below.

Referring to FIG. 4A, a first gate pattern 410 is formed on a first active region 402 of a substrate 400 and a second gate pattern 440 is formed on a second active region 432 of the substrate 400. The active regions 402 and 432 are divided by a device isolation layer 403. The first gate pattern 410 may include a first gate insulating layer 404, a first gate electrode 406 and a first hard mask layer 407 that sequentially stacked. The second gate pattern 440 may include a second gate insulating layer 434, a second gate electrode 436 and a second hard mask layer 437 that are sequentially stacked.

Referring to FIG. 4B, a photoresist is coated and selectively removed to form a first mask layer 450 covering the second active region 432. After that, SiN is deposited on the entire surface of the substrate 400 using PIIID under the condition that a bias is applied to the substrate 400 to form a first sacrifice layer 452.

Referring to FIG. 4C, as a first high concentration impurity doping, plasma doping using PIIID is adopted to implant a high impurity, for example AsH₄, into the substrate 400. The first sacrifice layer 452 functions as a disposable spacer during the first high concentration impurity doping. Impurities are not implanted into a portion of the first active region 402 adjacent to both sidewalls of the first gate pattern 410 and are implanted into the other first active region 402. Thus, a first deep source/drain 414 doped with N⁺ is formed at a position spaced apart from the both sidewalls of the first gate pattern 410.

Referring to FIG. 4D, the first sacrifice layer 452 is removed to expose the first active region 402. The first sacrifice layer 452 may be removed using, for example, a wet etching or a dry etching. However, when the first sacrifice layer 452 is removed, a plasma etching process using PIIID may be adopted so that the plasma etching is performed in-situ with a subsequent process.

Referring to FIG. 4E, as a first low concentration impurity process, plasma doping using PIIID is adopted to implant a low impurity, for example AsH₄, into the substrate 400. The first mask layer 450 may prevent impurities from being implanted into the second active region 432 and the first hard mask layer 407 may prevent impurities from being implanted into the first gate electrode 406. Thus, impurities are implanted into the first active region 402 where the first deep source/drain 414 is not formed to form a first LDD 412 doped with an N⁻ conductivity type having a depth smaller than the first deep source/drain 414. The first LDD 412 and the first deep source/drain 414 constitute a first junction region 416. As formations of the first sacrifice layer 452, the first deep source/drain 414 and the first LDD 412, and the removal of the first sacrifice layer 452 use PIIID, they may be performed in-situ.

Referring to FIG. 4F, the first mask layer 450 is removed. The first mask layer may be removed using, for example, an ashing process. The first mask layer 450 is removed to expose the second active region 432 including the second gate pattern 440.

Referring to FIG. 4G, a photoresist is coated and selectively removed to form a second mask layer 460 covering the first active region 402. After that, SiN is deposited on the entire surface of the substrate 400 using PIIID under the condition that a bias is applied to the substrate 400 to form a second sacrifice layer 462.

Referring to FIG. 4H, as a second high concentration impurity doping, plasma doping using PIIID is adopted to implant a high impurity, for example BF₃ into the substrate 400. The second sacrifice layer 462 functions as a disposable spacer during the second high concentration impurity doping. Impurities are not implanted into a portion of the second active region 432 adjacent to both sidewalls of the second gate pattern 440 and are implanted into the other second active region 432. Thus, a second deep source/drain 444 doped with P⁺ is formed at a position spaced apart from the both sidewalls of the second gate pattern 440.

Referring to FIG. 4I, the second sacrifice layer 462 is removed to expose the second active region 432. When the second plasma sacrifice layer 462 is removed, an etching process using PIIID may be adopted so that the etching process is performed in-situ with a subsequent process.

Referring to FIG. 4J, as a second low concentration impurity process, plasma doping using PIIID is adopted to implant a low impurity, for example BF₃, into the substrate 400. The second mask layer 460 may prevent impurities from being implanted into the first active region 402 and the second hard mask layer 437 may prevent impurities from being implanted into the second gate electrode 436. Thus, impurities are implanted into the second active region 432 where the second deep source/drain 444 is not formed to form a second LDD 442 doped with a P⁻ conductivity type having a depth smaller than the second deep source/drain 444. The second LDD 442 and the second deep source/drain 444 constitute a second junction region 446. As the formation of the second sacrifice layer 462, the second deep source/drain 444 and the second LDD 442, and the removal of the second sacrifice layer 462 adopt plasma doping using PIIID, they may be performed in-situ.

Referring to FIG. 4K, the second mask layer 460 is removed using, for example, an ashing process. After that, a first permanent spacer 418 is formed on both sidewalls of the first gate pattern 410 and a second permanent spacer 448 is formed on both sidewalls of the second gate pattern 440. As a result, a semiconductor device 40 including an NMOS field effect transistor 411 formed on the first active region 402 and a PMOS field effect transistor 441 formed on the second active region 432 may be embodied.

The fourth exemplary embodiment has a characteristic different from the first exemplary embodiment to third exemplary embodiment in that the deep source/drain 414 and 436 are formed before the LDD 412 and 442 are formed.

### Application Example

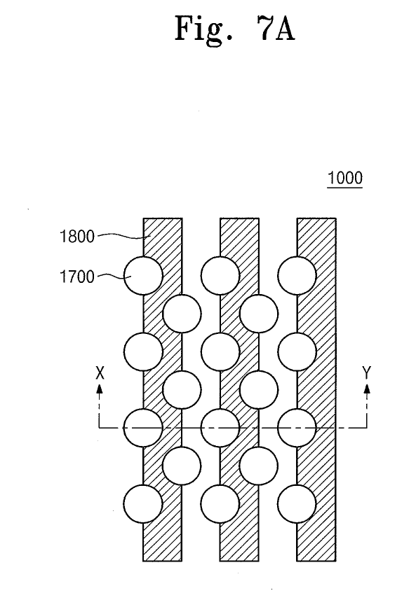

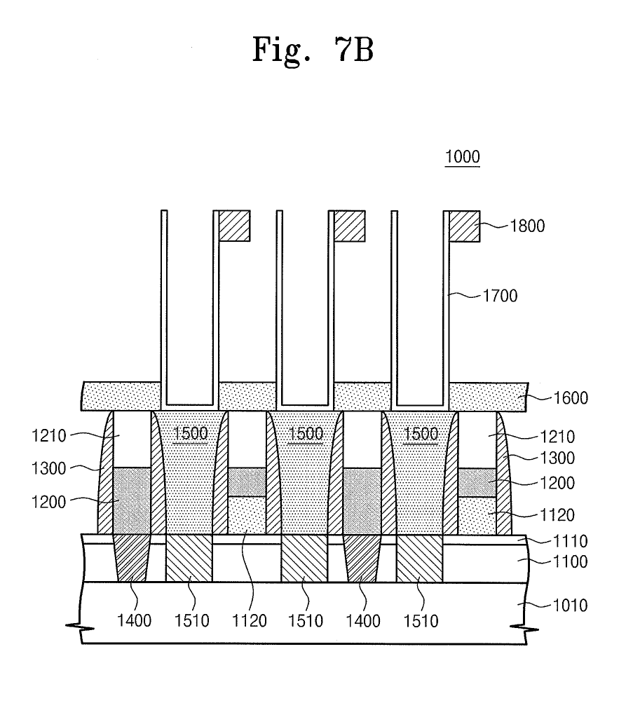

SiN which can be deposited at a low temperature using PIIID of some of the exemplary embodiments of the present invention may be applied to a bit line spacer and a capacitor supporting portion. FIG. 7A is a top plan view depicting an application example of a PIIID low temperature deposition layer according to an exemplary embodiment of the present invention. FIG. 7B is a cross sectional view taken along the line X-Y of FIG. 7a.

Referring to FIGS. 7A and 7B, a semiconductor device 1000 may include a bit line 1200 formed on an insulating layer 1100. The bit line 1200 may be formed of metal such as, for example, aluminum or copper. The insulating layer 1100 is formed on a substrate 1010 including cell transistors. The bit line 1200 is electrically connected to a cell transistor through a bit line contact 1400 formed of, for example, polysilicon. A capping layer 1210 may further be formed on the bit line by depositing, for example, SiN. A capacitor contact 1500 is formed between the bit lines 1200 and the capacitor contact 1500 is electrically connected to a capacitor 1700. The capacitor contact 1500 may be formed of, for example, polysilicon. The capacitor contact 1500 may directly be electrically connected to the substrate 1010 or may be electrically connected to the substrate 1010 through the medium of metal such as, for example, tungsten. Drawing numerals 1600 and 1120 represent an insulating layer and a drawing numeral 1110 represents a capping layer.

A bit line spacer 1300 is formed on a sidewall of the bit line 1200. The bit line spacer 1300 blocks a contact of the bit line 1200 and the capacitor contact 1500 to prevent the bit line 1200 and the capacitor contact 1500 from being electrically connected to each other. The bit line spacer 1300 may be formed of, for example, SiN. When SiN is formed by a general CVD process, a deposition temperature is generally about 600 degrees centigrade. If SiN is deposited at a high temperature, dopants contained in a source/drain of a cell transistor may diffuse, so that a dopant deactivation phenomenon may occur. If so, a thermal budget may become great because a thermal treatment may have to be performed again to activate dopants. That is, a deposition temperature of SiN used in the bit line spacer 1300 may occupy a large portion of the thermal budget. However, if the bit line spacer 1300 is formed by depositing SiN at a low temperature using PIIID of the embodiments of the present invention, a thermal budget may be reduced and a deactivation of a dopant may be suppressed. As a result, an operation speed of the cell transistor may increase.

Referring again to FIGS. 7A and 7B, a lower electrode of the capacitor 1700 may be formed in, for example, a cylinder shape. The capacitor 1700 of a cylinder shape has a vertically long shape and may readily fall down due to a stress applied from a side of the capacitor 700. To prevent this, a capacitor supporting portion 1800 formed of SiN may be formed at a side of a capacitor 1700.

When SiN is deposited by a general CVD process to form the capacitor supporting portion 1800, the dopant deactivation phenomenon may occur and the thermal budget may become great because a high temperature may be needed. In exemplary embodiments of the present invention, SiN is deposited at a low temperature using PIIID to form the capacitor supporting portion 1800. As a result, the difficulties described above can be solved.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of forming a low temperature deposition layer comprising:
providing a reaction gas to a substrate;
applying a bias to the substrate; and
forming a deposition layer on the substrate by plasma deposition using plasma ion immersion implantation and deposition (PIIID).

2. The method of claim 1, wherein the reaction gas includes silane (SiH₄) and nitrogen (N₂), and wherein the deposition layer includes silicon nitride (SiN).

3. The method of claim 2, wherein the providing of the reaction gas to the substrate includes providing a supplying speed of the reaction gas at a ratio of SiH₄:N₂ of about 1:10 to about 1:20.

4. The method of claim 3, wherein the applying of the bias to the substrate includes applying the bias of about 1 to about 5 killivolts (kV) to the substrate.

5. The method of claim 3, wherein the plasma deposition is provided under the condition of a deposition pressure of about 15 to about 100 milli-torr (mT).

6. The method of claim 1, further comprises:
igniting a plasma needed to deposit the plasma using an argon plasma; and
preprocessing the substrate using nitrogen plasma.

7. A method of manufacturing a semiconductor device, the method comprising:
forming a mask layer exposing a gate pattern on a substrate on which the gate pattern is formed;
forming a sacrifice layer on the mask layer and on a substrate not covered by the mask layer using plasma ion immersion implantation and deposition (PIIID); and
doping a substrate adjacent to both sidewalls of the gate pattern with an impurity.

8. The method of claim 7, wherein the forming of the sacrifice layer comprises depositing silicon nitride at a temperature that the mask layer is not burned during a deposition of the plasma under the condition that a bias is applied to the substrate.

9. The method of claim 7, wherein the doping of the substrate with an impurity comprises implanting impurities into both sidewalls of the gate pattern by plasma doping using the PIIID and preventing impurities from being implanted into the substrate using the sacrifice layer formed on both sidewalls of the gate pattern as a spacer.

10. The method of claim 7, wherein before the forming of the sacrifice layer, further comprising forming a lightly doped drain in the substrate adjacent to both sidewalls of the gate pattern by plasma doping using the PIIID.

11. The method of claim 10, wherein the doping of the substrate with an impurity comprises forming a high concentration deep source/drain having a small area and a great depth compared with the lightly doped drain by plasma doping using the PIIID.

12. The method of claim 11, wherein before the forming of the high concentration deep source/drain, further comprising:
selectively etching the sacrifice layer by plasma etching using the PIIID to expose the lightly doped drain and to form a disposable spacer on both sidewalls of the gate pattern at the same time; and
implanting impurities into the lightly doped drain to form the high concentration deep source/drain and prevent impurities from being implanted into the lightly doped drain under the disposable spacer.

13. The method of claim 1, wherein after the forming of the high concentration deep source/drain, further comprising selectively removing the sacrifice layer by plasma etching using the PIIID to form permanent spacers on both sidewalls of the gate pattern.

14. The method of claim 7, wherein the doping of the substrate with an impurity comprises implanting impurities into the substrate adjacent to both sidewalls of the gate pattern by plasma doping using the PIIID and preventing impurities from being implanted into the substrate under the sacrifice layer formed on both sidewalls of the gate pattern, to form a high concentration deep source/drain on the substrate spaced apart from the both sidewalls of the gate pattern.

15. The method of claim 14, further comprising:
removing the sacrifice layer to expose the substrate including the high concentration deep source/drain; and
implanting impurities into the exposed substrate by plasma doping using the PIIID and implanting impurities where an implantation of an impurity is prevented by the sacrifice layer, to form a lightly doped drain having a shallow depth compared with the high concentration deep source/drain.

16. A method of manufacturing a semiconductor device, the method comprising:
forming a gate pattern on an active region of a substrate; and
implanting a low concentration impurity and a high concentration impurity into the substrate to form a lightly doped drain and a high concentration deep source/drain in an active region adjacent to both sidewalls of the gate pattern,
wherein the forming of the lightly doped drain comprises:
forming a mask layer on the substrate; and
implanting the low concentration impurity into the active region adjacent to both sidewalls of the gate pattern by plasma doping using plasma ion immersion implantation and deposition (PIIID), and
wherein the forming of the high concentration deep source/drain comprises:
forming a sacrifice layer on an entire surface of the substrate by plasma deposition using the PIIID; and
implanting the high concentration impurity into the lightly doped drain by plasma doping using the PIIID to form the high concentration deep source/drain having a small width and a great depth compared with the lightly doped drain.

17. The method of claim 16, wherein the forming of the high concentration deep source/drain comprises implanting the high concentration impurity into the lightly doped drain under the condition that the sacrifice layer is not removed and preventing the high concentration impurity from being implanted into the lightly doped drain under the sacrifice layer formed on both sidewalls of the gate pattern.

18. The method of claim 17, wherein after the forming of the high concentration deep source/drain, further comprising selectively removing the sacrifice layer by plasma etching using the PIIID to form a permanent spacer on both sidewalls of the gate pattern.

19. The method of claim 16, wherein the forming of the high concentration deep source/drain comprises:
selectively removing the sacrifice by plasma etching using the PIIID to expose the lightly doped drain and form a disposable spacer on both sidewalls of the gate pattern at the same time; and
implanting the high concentration impurity into the exposed lightly doped drain and preventing the high concentration impurity from being implanted into the lightly doped drain under the disposable spacer.

20. The method of claim 19, wherein after the forming of the high concentration deep source/drain, further comprising:
removing the disposable spacer; and
forming a permanent spacer on both sidewalls of the gate pattern.
